(19) United States
(12) Patent Application Publication
(10) Pub. No.: US 2007/0236295 A1
(43) Pub. Date: Oct. 11, 2007

(54) FM Power Amplifier With Antenna Power Control

(75) Inventor: Cary L. Delano, Los Altos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Leadis Technology, Inc., Sunnyvale, CA (US)

(21) Appl. No.: 11/688,816

(22) Filed: Mar. 20, 2007

Related U.S. Application Data
(60) Provisional application No. 60/784,638, filed on Mar. 21, 2006.

(51) Int. Cl. H03F 3/191

(52) U.S. Cl. 330/302

(57) ABSTRACT

An RF power amplification system having a power amplifier, a matching network, and an antenna power controller which compares a voltage at the matching network output to a voltage at the matching network input and uses a result of that comparison to manipulate the power amplifier and/or the matching network, to control the power applied to the antenna. In one embodiment, the power controller tristates one or more of a plurality of parallel power amplifier devices in the amplifier, to control the antenna power. In another embodiment, the power controller manipulates a plurality of parallel resistors or other impedances in the power amplifier, switching some impedances in and some impedances out, to maximize the power coupling to the antenna or to operate the amplifier device in a maximally efficient operating range.

### RELATED APPLICATION

The present application claims benefit under 35 USC 119(e) of U.S. provisional Application No. 60/784,638, filed on Mar. 21, 2006, entitled “Adaptive Biasing Based on Volume Control Setting,” the content of which is incorporated herein by reference in its entirety.

### BACKGROUND OF THE INVENTION

1. Technical Field of the Invention

This invention relates generally to radio frequency (RF) power amplifiers, and more specifically to improved means for controlling the power delivered to the antenna.

### BACKGROUND ART

FIG. 1 illustrates a conventional RF power amplification system 10 according to the prior art. The system includes a power amplifier PA1 which is provided with voltage reference supply signals Vcc and ground, and which receives an ECL or PECL differential RF input signal V+ and V−.

The power amplifier includes an emitter-coupled pair of transistors T1 and T2 which are coupled to Vcc via first and second resistors R1 and R2, respectively. The output power of the amplifier is determined by a variable current source VCS1, and by the differential input signals. The amplifier produces an output signal PAout which is input to a matching network which performs impedance matching etc. to generate an RF signal which is driven onto the antenna A1.

The output resistors are not good for power efficiency. This type of amplifier is typically used in low power transmission such as in aftermarket FM transmitters which are required to transmit below a power threshold specified by the FCC.

The output power delivered to the antenna can be adjusted by controlling the variable current source, as is known in the art.

FIG. 2 illustrates another conventional RF power amplification system 20 according to the prior art. This system is used in applications where power efficiency is important, such as mobile telephones and other battery operated devices. The system includes a linear power amplifier PA2 which receives an RF input signal RFin and produces an RF power amplifier output signal PAout. A matching network receives the PAout signal and drives an RFout signal onto the antenna A2. The power amplifier is typically implemented as a single transistor biased in Class AB mode, with LC filters and/or microstrips to maximize power transfer.

The power efficiency of the linear amplifier as it delivers power to the antenna is adjusted by controlling a voltage regulator which provides the Vcc voltage reference to the power amplifier. The voltage regulator is able to improve the efficiency of the linear amplifier by lowering VCC for lower output voltages, so the output voltage is closer to the new VCC; this causes the linear amplifier to be operated in a more efficient portion of the Class AB efficiency curve (illustrated in FIG. 3).

The voltage regulator may be an LDO or a switching regulator. LDOs are less expensive than switching regulators and produce less noise, but have high power dissipation. Switching regulators are more expensive than LDOs and add switching noise to the output. And although switching regulators are more efficient than LDOs, the power they dissipate is still non-trivial in applications such as mobile telephones.

What is needed, then, is an RF power amplification system which has an improved mechanism for adjusting antenna power.

### BRIEF DESCRIPTION OF THE DRAWINGS

FIG. 1 shows an RF power amplification system according to the prior art, in which the antenna power is controlled by manipulating the amplifier's variable current source.

FIG. 2 shows another RF power amplification system according to the prior art, in which the antenna power is controlled by manipulating the amplifier's Vcc voltage reference.

FIG. 3 shows an exemplary Class AB efficiency curve.

FIG. 4 shows an RF power amplification system according to one embodiment of this invention, in which the antenna power is controlled by manipulating a resistor bank coupled to the amplifier's output.

FIG. 5 shows an RF power amplification system according to another embodiment of this invention, in which the antenna power is controlled by manipulating parallel sections of the amplifier itself or by manipulating the matching network.

FIG. 6 shows an RF power amplification system similar to that of FIG. 5, but in which the resistive elements are replaced by generalized impedance elements.

FIG. 7 shows an example of a power efficient amplifier with a variable matching network.

FIG. 8 shows a higher level abstraction view of the RF power amplification system of this invention, in which the antenna power is controlled by manipulating an adjustable power amplifier and/or an adjustable matching network.

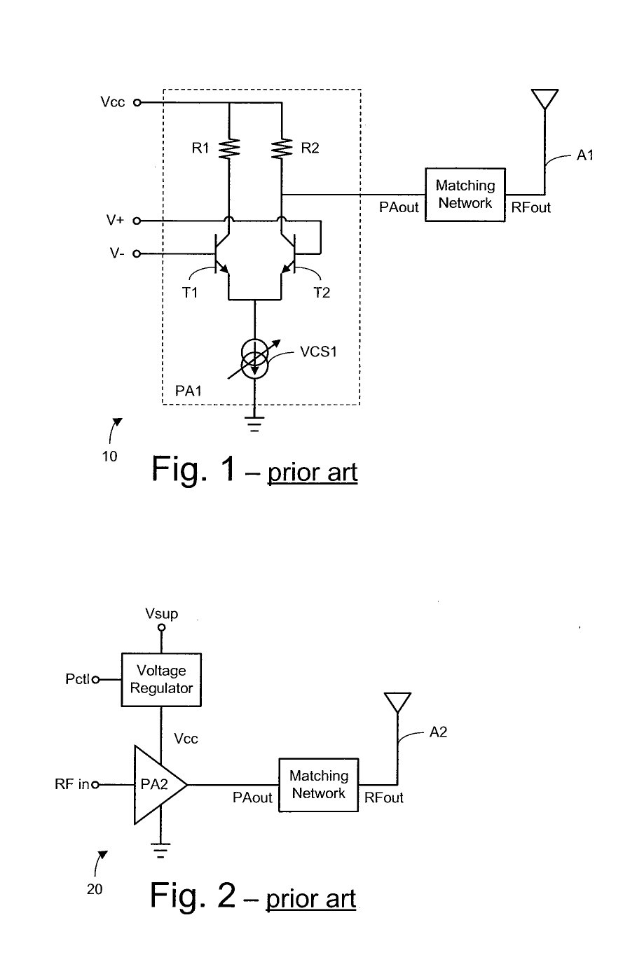

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

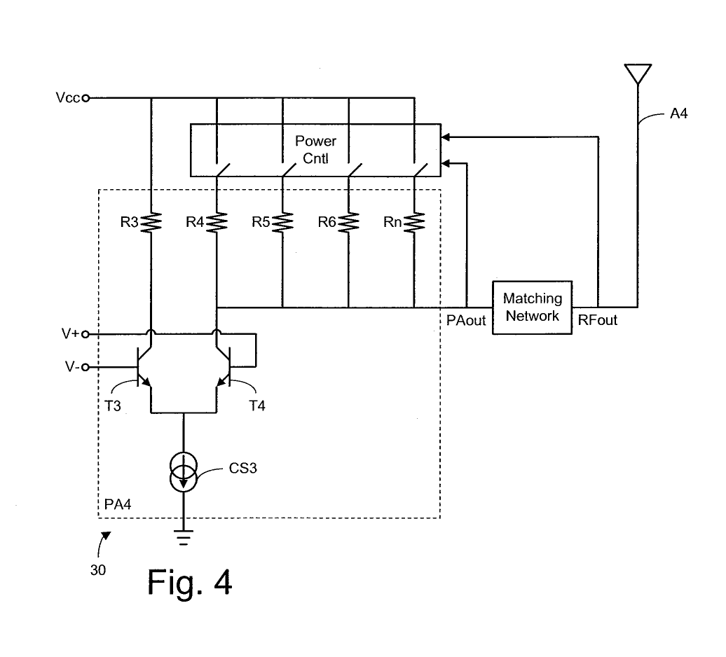

FIG. 4 illustrates an RF power amplification system 40 according to one embodiment of this invention. The system includes an RF power amplifier PA4 which receives an ECL or PECL input signal pair V+ and V−. The power amplifier includes an emitter-coupled transistor pair T3 and T4 which are driven by a current source CS3 which can be either a constant current source or a variable current source. One of the T3, T4 emitter-coupled pair is coupled to Vcc via a first resistor R3, and the other is coupled to VCC via a plurality of resistors R4 to Rn which are coupled in parallel.

The latter of the T3, T4 emitter-coupled pair is coupled to provide an RF power amplifier output signal PAout to a matching network which can be either fixed or variable. The matching network drives an antenna A4.

An antenna power controller (Power Cntl) mechanism is coupled to selectively de/couple each of the parallel resistors R4 to Rn from/to Vcc, thereby adjusting the RF power supplied to the antenna. In one embodiment, the power controller includes a plurality of switches each coupled between Vcc and a respective one of the resistors. In one embodiment, the power controller senses the voltages on the input of the matching network (at the PAout signal) and the output of the matching network (at the RFout signal), and uses the voltages to control the switches. By sensing PAout and RFout, the power delivered to the antenna is able to be controlled even as the impedance of the antenna changes due to variations in its shape or its surrounding environment. This is very useful in applications such as aftermarket FM transmitters, where the antenna folds and changes impedance drastically

The values of the resistors, and the operating characteristics of the selection mechanism within the power controller, may be specified according to the particular dictates of the application at hand. For example, in applications that require high power efficiency, the resistors can be replaced by low loss elements such as inductors, capacitors and/or microstrips. Their specification is well within the abilities of those of ordinary skill in this art, armed with the teachings of this disclosure. There are a variety of reasons why, in various applications, it may be desirable to adjust the antenna power, and the principles of this invention may be applied to various systems accordingly.

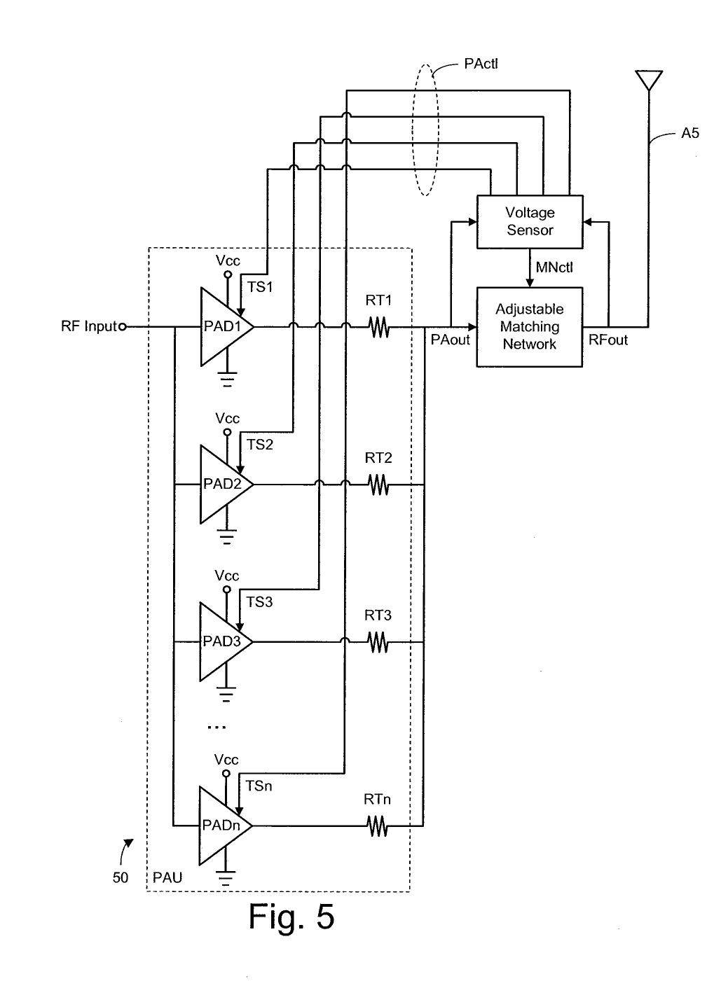

FIG. 5 illustrates an RF power amplification system 50 according to another embodiment of this invention. The system includes a power amplification unit PAU which includes a plurality of parallel power amplification devices PAD1 through PADn. Each power amplification device receives the RF input signal. Each power amplification device has an associated Thevenin resistance RT1 through RTn at its output. The power amplification devices in parallel drive a PAout signal to a matching network which may be fixed or variable. The matching network drives an RFout signal onto an antenna A5.

A voltage sensor is coupled to sense the voltages on the PAout signal and the RFout signal, to determine the antenna power. The voltage sensor is adapted to manipulate the matching network via a MNctl signal and/or to manipulate the power amplifier unit via a PActl signal, to control the power applied to the antenna.

Both FIGS. 4 and 5 used lossy resistors to control the output power. These adjustments can also be done with a variety of configurations using lossless inductors, capacitors, and/or microstrips.

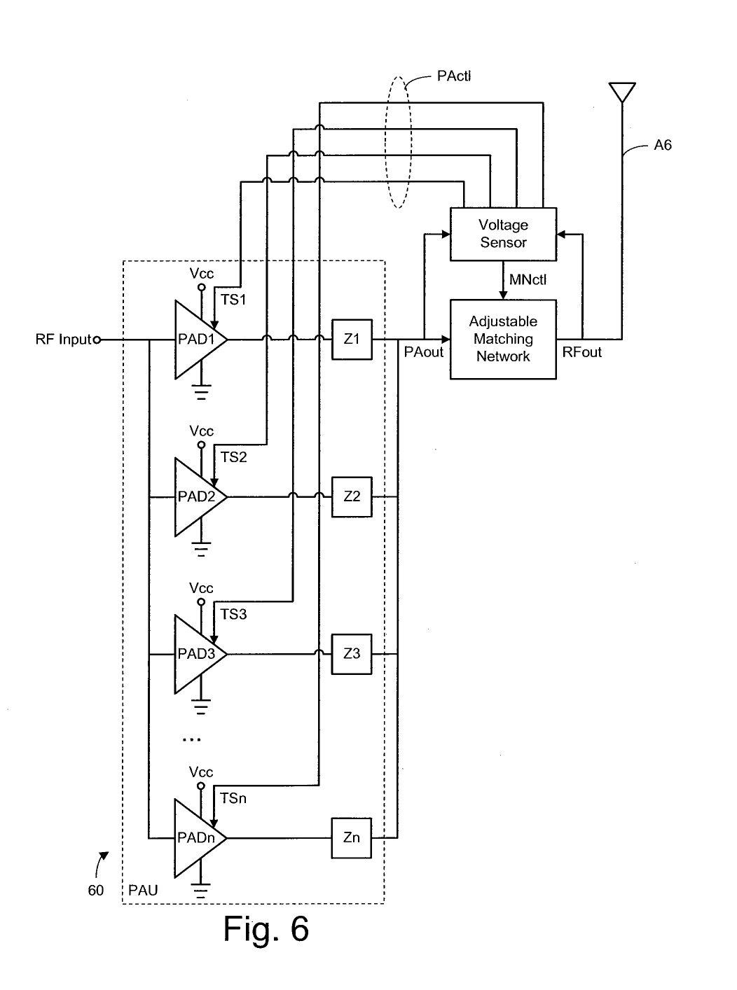

FIG. 6 illustrates an RF power amplification system 60 similar to that of FIG. 5, except that the Thevenin resistances (RT1 through RTn) have been replaced with generalized impedances Z1 through Zn.

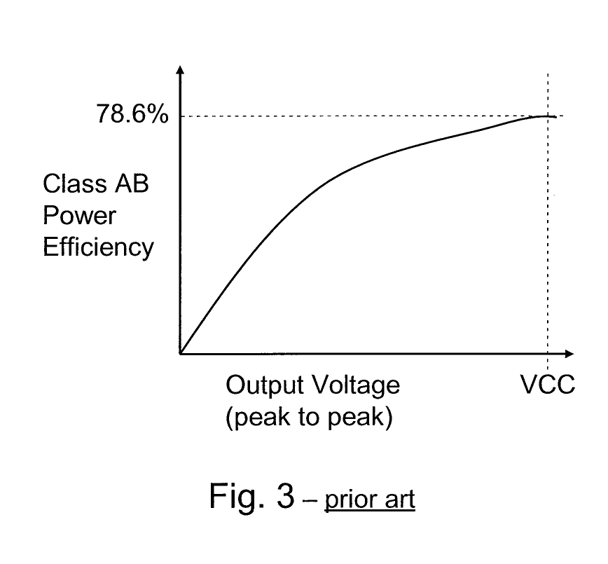

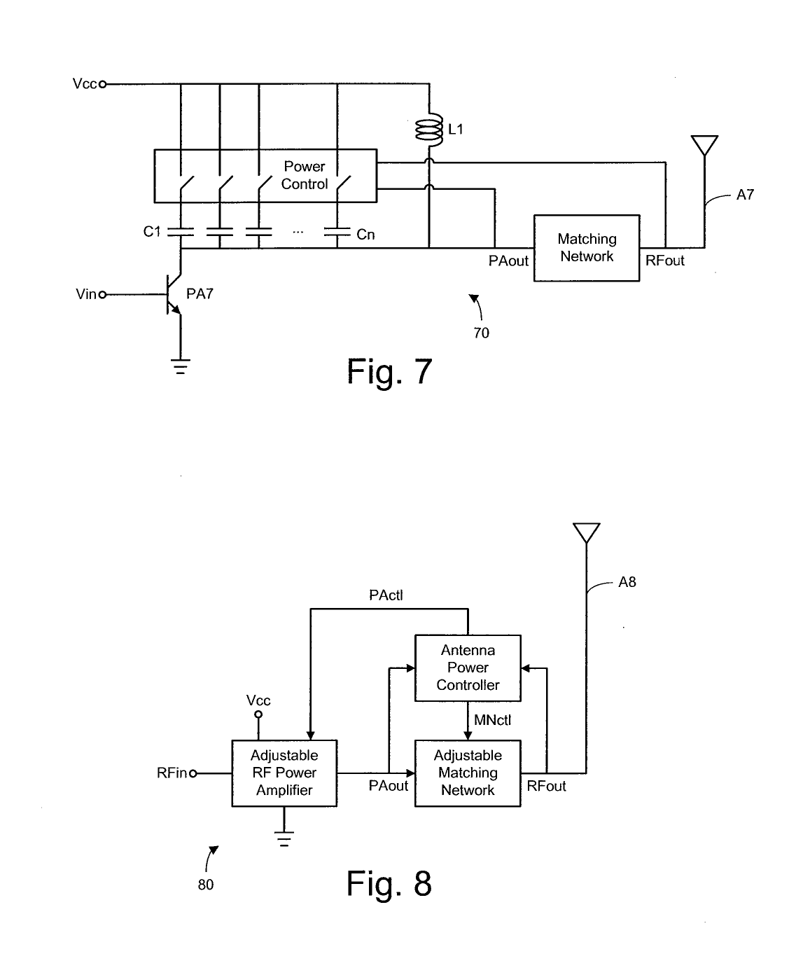

FIG. 7 illustrates an RF power amplification system 70 according to another embodiment of this invention, as it can be applied to a typical mobile telephone RF power amplifier. In this embodiment, capacitors are switched on the output of a power amplifier PA7. This output network of the power amplifier interacts with the matching network and affects the amount of power transferred to the antenna A7. The voltage required on the node PAout for a given power delivered to the antenna is different for various switch settings. This means that power control can be achieved by manipulating the switch settings. In one embodiment, the control is done in order to keep the signal swing on PAout as large as possible given the linearity constraints of the amplifier and the target output power to the antenna. This maximizes the efficiency of the amplifier by pushing the amplifier operating point far to the right (close to VCC) on the curve shown in FIG. 3.

Because the components allow for a matching network optimization, there is an added benefit of being able to fine tune the power match. Switching capacitors in order to provide a maximum power transfer requires typically about a 20% range. That is a subset of this case since the capacitors need to have a much larger range to intentionally go away from the power match to reduce output power.

It should be added that they are many ways to switch inductors, capacitors, and microstrips to control the output power with high efficiency. FIG. 7 is intended to be illustrative and there are many ways one skilled in the art will find to effectively adjust the composite matching network with low loss, given the teachings of this disclosure.

FIG. 8 illustrates a generalized RF power amplification system 80 according to the principles of this invention. The system includes an RF power amplifier and a matching network, at least one of which is adjustable. The system includes an antenna power controller which senses the signals into and out of the matching network, and is coupled to consequently control at least one of the power amplifier (by a signal PActl) and the matching network (by a signal MNctl), to adjust the power applied to the antenna A8.

Many antennas are subjected to unpredictable reconfiguration which alters their impedance. For example, a cell phone user may occasionally fail to fully deploy the cell phone's retractable antenna. Or a user of a wearable music player may fold or otherwise change the shape of the player's headphone cable which serves double duty as its FM antenna. Or a large truck may park near a broadcast tower and cause reflections and even sink RF power via eddy current induction. Impedance ratio changes between the power amplifier (or matching network) and the antenna can cause changes in the power delivered to the antenna and/or the power radiated by the antenna.

In some embodiments, the power controller of any embodiment of this invention may take advantage of the fact that the impedance Zmn of the matching network is known, in calculating the impedance Zant of the antenna.
Vant=Vpa*Zant/(Zmn+Zant)
solves to
Zant=Zmn*((Vant/Vpa)/(1−(Vant/Vpa)))
where:
Vant is the voltage at the RFout signal output from the matching network,
Vpa is the voltage at the PAout signal output by the power amplifier,
Zmn is the impedance of the matching network, and
Zant is the impedance of the antenna

The radiated power Pant of the antenna is
Pant=(Vantˆ2)/Zant

The power controller can thus calculate the antenna power and adjust the power amplifier and/or the matching network to obtain a desired antenna power. For example, it may be desirable to achieve a constant radiated power level.

In other embodiments, PAout is monitored to maximize the efficiency of the adjustable RF amplifier.

### CONCLUSION

When one component is said to be “adjacent” another component, it should not be interpreted to mean that there is absolutely nothing between the two components, only that they are in the order indicated.

The various features illustrated in the figures may be combined in many ways, and should not be interpreted as though limited to the specific embodiments in which they were explained and shown.

Although in various drawings there are specific numbers of channels actually illustrated, the invention may be practiced with any number of channels, each having their own load and their own amplifier.

Those skilled in the art, having the benefit of this disclosure, will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. A power amplification system for receiving an input signal and couplable to an antenna, the power amplification system comprising:
an RF power amplifier having an input for receiving the input signal and having an output;
a matching network having an input coupled to the output of the power amplifier and having an output couplable to the antenna; and
a power controller coupled to manipulate at least one of the RF power amplifier and the matching network in response to the comparison;
whereby power applied to the antenna is controlled.

2. The power amplification system of claim 1 wherein:
the power controller is coupled to compare a characteristic of a signal at the input of the matching network to a characteristic of a signal at the output of the matching network; and
the manipulation is in response to the comparison.

3. The power amplification system of claim 2 wherein:
the power controller is coupled to control the RF power amplifier in response to the comparison.

4. The power amplification system of claim 3 wherein:
the RF power amplifier comprises one of an emitter-coupled transistor pair and a source-coupled transistor pair, having an output;
a plurality of impedances coupled in parallel to the output of the one of the emitter-coupled transistor pair and the source-coupled transistor pair; and
wherein the power controller comprises a plurality of switches selectively operable to connect respective ones of the impedances to a voltage reference supply.

5. The power amplification system of claim 4 wherein the plurality of impedances comprises:
a plurality of resistors.

6. The power amplification system of claim 3 wherein:
the RF power amplifier comprises a plurality of amplifier devices coupled in parallel to the output of the RF power amplifier; and
the power controller is coupled to selectively tristate at least one of the amplifier devices.

7. A radio frequency power amplifier comprising:
an amplifier device having an input for receiving an input signal and having an output;
a matching network having an input coupled to the output of the amplifier device and having an output couplable to drive an antenna;
a plurality of impedances coupled in parallel to the output of the amplifier device;
a power control unit coupled to selectively couple respective ones of the plurality of impedances to a voltage supply reference.

8. The radio frequency power amplifier of claim 7 wherein the voltage supply reference comprises one of VCC and GND.

9. The radio frequency power amplifier of claim 7 wherein the plurality of impedances comprises a plurality of capacitors.

10. The radio frequency power amplifier of claim 7 wherein:
the power control unit is coupled to the input of the matching network and the output of the matching network and determines which of the capacitors to couple to the voltage supply reference based at least in part on a comparison of a signal at the input of the matching network and a signal at the output of the matching network.

11. The power amplification system of claim 7 further comprising:
an inductor coupled between the voltage supply reference and the output of the amplifier device.

12. The power amplification system of claim 7 further comprising:
the antenna coupled to the output of the matching network.

13. The power amplification system of claim 7 wherein the amplifier device comprises:
only a single transistor.
